(19) United States
(12) Patent Application Publication
(10) Pub. No.: US 2007/0155128 A1
(43) Pub. Date: Jul. 5, 2007

(54) Method for forming trench

(75) Inventor: Kee Joon Choi, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,095

(22) Filed: Dec. 26, 2006

(30) Foreign Application Priority Data
Dec. 29, 2005 (KR) 10-2005-0133184

(51) Int. Cl. H01L 21/76

(52) U.S. Cl. 438/424; 438/426

(57) ABSTRACT

Provided is a method for forming a trench, capable of rounding a top corner without adding a separate mask or process. In the method, first and second insulating layers are stacked on a substrate having an isolation region and an active region. Subsequently, a photoresist pattern is formed on the second insulating layer, and the first and second insulating layers are patterned using the photoresist pattern as a mask to expose a portion of a substrate in the isolation region. After that, the substrate is etched using the first and second pad insulating layers as a mask to form an STI region such that an upper width of the STI region is greater than a lower width of the STI region.

### BACKGROUND OF THE INVENTION

1. Field of the Invention

The present invention relates to a method for forming a shallow trench isolation (STI), and more particularly, to a method for forming an STI that effectively rounds a top corner.

2. Description of the Related Art

It is important for product yield to round a top corner of an STI when forming an STI region in order to isolate devices in a general semiconductor device, e.g., a liquid crystal display (LCD) driver integrated circuit (IC).

Particularly, in the case where a portion of a gate oxide layer located at a top corner of an STI region is shallow, but the gate is in a product to which a high voltage is applied, an electric field may be concentrated on this top corner, which increases I_{off} (e.g., a leakage current of the transistor, or a hump characteristic) and decreases a breakdown voltage of the gate oxide layer.

To solve the problems caused by the top corner of the STI region, lots of solutions have been proposed.

For example, Si-migration such as a re-oxidation process after an STI region is formed, and an N₂ push oxidation has been proposed. That is, after an STI region is formed, a top corner of an STI region may be rounded during a liner oxidation process itself, which is a surface oxidation process.

FIG. 1 is a view illustrating a surface of an STI at temperature of 1000° C., and FIG. 2 is a profile photo when a re-oxidation process has been performed at a temperature of 950° C. Both processes show that a corner of the STI is overhung and is not ideally rounded. That is, as described above, there is limitation in rounding a top corner of an STI using only an STI surface oxidation process or a re-oxidation process.

Also, since one oxidation process and two cleaning processes should be additionally performed in order to re-oxidize the substrate and round a top corner of an STI during an actual manufacturing process, these additional processes restrict manufacturing through-put. Furthermore, a high voltage (HV) well process should be performed on a substrate before the STI process on an LCD IC (LDI device). In this case, a dose of the HV well that is adjacent to an STI may be lost, and a leakage current may increase.

When a surface oxidation process, which provides a sacrificial oxide (SACOX), is performed on a surface of the STI, the dose of the HV well that is adjacent to the STI can be lost, and a leakage current may increase.

### SUMMARY OF THE INVENTION

Accordingly, the present invention is directed to a method for forming a trench that substantially obviates one or more problems due to limitations and disadvantages of the related art.

An object of the present invention is to provide a method for forming a trench, capable of effectively rounding a top corner by setting process conditions without a separate mask or process.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, there is provided a method for forming a trench, including: stacking a first insulating layer and a second insulating layer on a substrate having an isolation region and an active region; forming a photoresist pattern on the second insulating layer; patterning the second insulating layer and the first insulating layer; and etching the substrate using the first and second insulating layers as a mask to form a trench such that an upper width of the trench is greater than a lower width of the trench.

Rounding a top corner of the shallow trench isolation region may include increasing an inner angle θ and a radius of an inscribed circle at the top corner of the trench by controlling an upper diameter and a lower diameter of the shallow trench isolation region, and/or by controlling a slope of the shallow trench isolation region.

The method may further include increasing a pullback length of the first insulating layer.

Rounding a top corner of the trench may also (or alternatively) comprise controlling a time of dipping the top corner in an HF-containing medium during a cleaning process.

A corner rounding radius of the top corner of the trench may be calculated using the equation: R=tan{[(θ^{α}/2)][a^{β}+b]}, where θ=tan⁻¹[{(e−f)/2}/g]+π/2, a is a pullback length of the first pad insulating layer, b is a pullback length of the second pad insulating layer, a={(C1×T1)²−C²}^{0.5}, b=C2×T2, α and β are weight factors of an oxidation process performed on the trench, C1 is an etching rate (Δ/sec) of the first insulating layer, C2 is an etching rate (Δ/sec) of the second insulating layer, T1 is an etching time (sec) of the first insulating layer, and T2 is an etching time (sec) of the second insulating layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a related art profile photo when an STI region is surface-oxidized at temperature of 1000° C.;

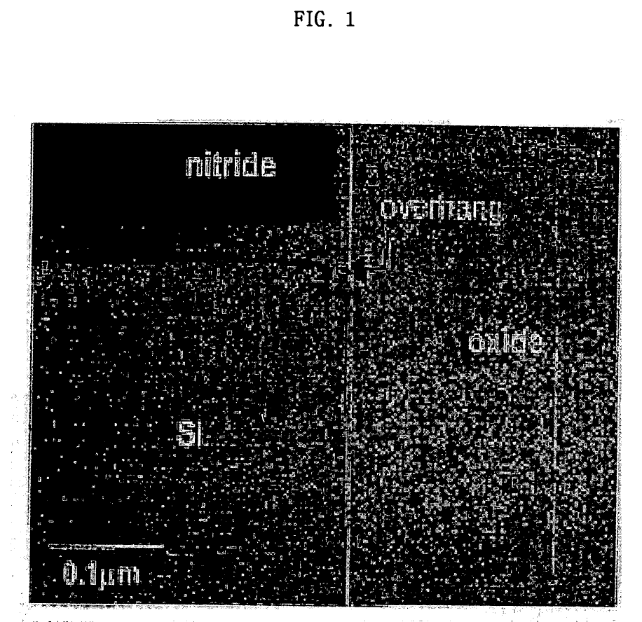

FIG. 2 is a related art profile photo when an STI region is re-oxidized at a temperature of 950° C.;

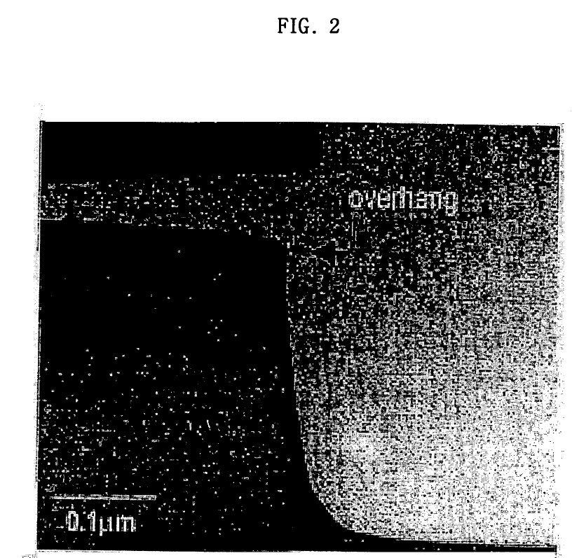

FIG. 3 is a view a method for rounding an STI corner according to the present invention; and

FIG. 4 is a cross-sectional view illustrating a related art STI region having an oxide layer whose pullback length is short, which is provided for comparison with the STI region of FIG. 3.

### DETAILED DESCRIPTION OF THE INVENTION

Reference will now be made in detail to the preferred embodiments of the present invention, examples of which are illustrated in the accompanying drawings. The preferred embodiments are not provided for limiting the scope of the present invention but for exemplary purpose only.

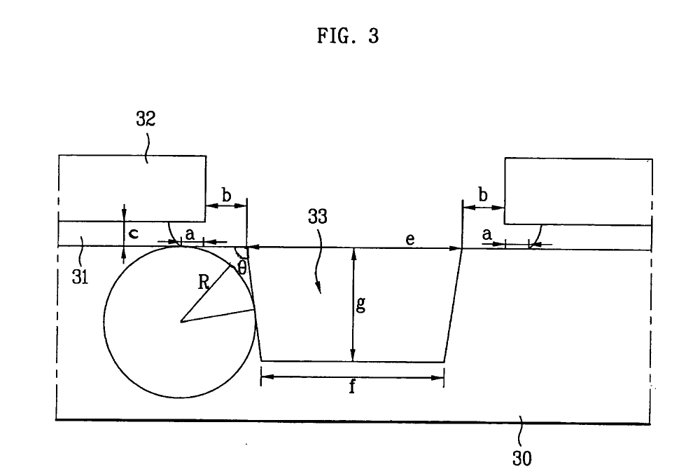

FIG. 3 is a view a method for rounding an STI corner according to the present invention.

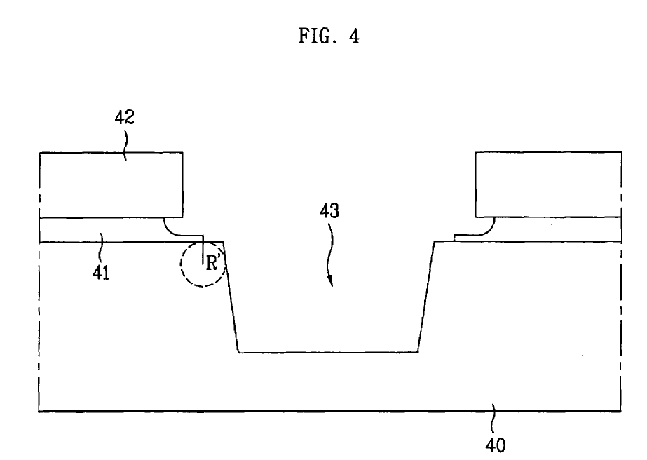

FIG. 4 is a cross-sectional view illustrating a related art STI region having an oxide layer whose pullback length is short, which is provided for comparison with the STI region of FIG. 3.

Referring to FIG. 3, according to a method for forming a trench, a first (pad) insulating layer 31 and a second insulating layer 32 are sequentially stacked on a substrate 30 having an isolation region and an active region defined therein. The first pad insulating layer 31 may comprise an oxide (e.g., silicon dioxide, formed by wet or dry thermal growth or chemical vapor deposition [CVD]), and the second insulating layer 32 may comprise a nitride (e.g., silicon nitride, formed by chemical vapor deposition [CVD]).

After that, a photoresist pattern (not shown) having an opening where the isolation region is to be formed is formed on the second insulating layer 32 using photolithography. Subsequently, the second and first insulating layers 32 and 31 are sequentially etched using the photoresist pattern as a mask to expose a portion of the substrate 30 located in the isolation region.

Next, the photoresist pattern is removed, and the substrate 30 is etched using the first and second pad insulating layers 31 and 31 as a mask to form an STI region 33 whose top corner is rounded.

At this point, the present invention can use a method of controlling a slope of the STI region 33 by controlling an upper diameter and a lower diameter of the STI region 33, increasing a pullback length of the first pad insulating layer 31, or lengthening a time of dipping a top corner in an HF-containing medium when cleaning a surface of the STI region 33 in order to round the top corner of the STI region 33. The slope of the STI region 33 may be controlled by controlling the upper diameter and the lower diameter of the STI region 33, increasing the pullback length of the first (pad) insulating layer 31, and/or increasing a radius of an inscribed circle at the top corner.

The above-described methods can be controlled depending on a point and a weight factor that can be increased for each operation.

A radius of the inscribed circle at the top corner of the STI region 33 is a radius of a circle contacting an inclined portion (a slope portion) of the STI region 33 and an end portion of the first pad insulating layer 31 on the inclined portion. As this radius increases, an extent to which the substrate 30 is exposed during an oxidation process for subsequent cleaning increases. Accordingly, rounding of the top corner can be induced during an STI oxide layer forming process.

As described above, a radius of the circle at the top corner on one side of the STI region 33 should be increased to advantageously round the top corner.

For example, FIG. 4 illustrates a related art STI region where a pullback length of an oxide layer pad is short, which is provided for comparison with the STI region of FIG. 3. As the pullback length is short, a radius of a circle at the top corner on one side of the STI region is small. Accordingly, the top corner of the STI region may be more difficult to round. Reference numerals 40, 41, 42, and 43 refer to a substrate, a first pad insulating layer, a second pad insulating layer, and an STI region, respectively.

In more detail, the following methods can be used in order to improve rounding of the top corner of the STI region 33 by increasing the radius of the circle at the top corner of the STI region 33.

First, a slope of the STI region 33 may be made gentle by controlling an upper diameter and a lower diameter of the STI region 33. That is, an inner angle θ of the top corner of the STI region can be increased, as shown in FIG. 3.

Second, the first (pad) insulating layer 31 can have a sufficient oxide layer pullback.

In the above description, a corner rounding radius can be calculated using Equation 1:

R=tan{[(θ^{α}/2)][a^{β}+b]}, Equation 1

where θ=tan⁻¹[{(e−f)/2}/g]+π/2.

Referring to FIG. 3, “a” is a pullback length of the first pad insulating layer 31, and can be given or determined by a={(C1×T1)²−C²}^{0.5}; and “b” is a pullback length of the second insulating layer 32, and can be given by b=C2×T2. α and β are weight factors of an oxidation process performed on the STI trench. Generally, the trench can be oxidized by conventional wet or dry thermal oxidation (e.g., of silicon) to form a liner oxide in the STI trench.

As shown in FIG. 3, a thickness of the first (pad) insulating layer 31 is “c”, an upper diameter of the STI region 33 is “e”, a lower diameter of the STI region 33 is “f”, and a depth of the STI region 33 is “g”.

Calculating using Equation 1 gives R=tan(θ/2)×(a+b).

Also, C1 is an etching rate (Å/sec) of the first (pad) insulating layer 31, C2 is an etching rate (Å/sec) of the second insulating layer 32, T1 is an etching time (sec) of the first insulating layer 31, and T2 is an etching time (sec) of the second insulating layer 32.

Next, as a method of rounding the top corner of the STI region 33, a time of dipping the top corner in an HF-containing medium can be lengthened when a cleaning process is performed on a surface of the STI region 33. The HF-containing medium generally refers to a solution of HF in deionized (DI) water, where the HF may be buffered (e.g., with ammonia, in which case the HF-containing medium may comprise a conventional buffered oxide etch solution, or BOE solution), and in which the ratio of concentrated HF to DI water may be from 1:1, 1:2, or 1:4 to 1:20, 1:50, or 1:100 by volume (or any range therein). Alternatively, the HF-containing medium may comprise a chamber in which the substrate with the trench(es) therein is exposed to HF vapor (which may or may not further include water vapor and which may or may not further include a plasma formed from such species).

Description will be made for the case where a radius of a circle at a top corner is increased (that is, a slope of the STI region is made gentle), and the case where the radius is decreased. The data obtained through experiment for measuring a thickness of an oxide layer at the top corner formed by an oxidation process and dependant on a time of dipping the top corner in HF during a cleaning process will be described for the above two cases.

A first experiment has been performed on a sample A where a slope of an STI region is steep, and a radius R of an inscribed circle at a top corner is 200 Å. The same experiment has been performed on a sample B where a slope of an STI region is gentle, and a radius R of an inscribed circle at a top corner is 400 Å. A dipping time in an HF solution is 240 seconds during a cleaning process of both sample A and sample B.

When the dipping time in HF is 240 seconds, a thickness of an oxide layer at the top corner is 260 Å for sample A, and a thickness of an oxide layer is 330 Å for sample B when the oxide layer in the STI region is formed. Therefore, a thickness of an oxide layer at a top corner is relatively thick when the radius of the circle at the top corner of the STI region is relatively large (sample B), as compared to the sample A where a radius of the circle at the top corner of the STI region is relatively small.

A second experiment has been performed on a sample C where a slope of an STI region is steep and a radius R of an inscribed circle at a top corner of a trench is 200 Å, and on a sample D where a slope of an STI region is gentle, and a radius R of an inscribed circle at a top corner of a trench is 400 Å. A dipping time in HF is 420 seconds during the cleaning process of the sample C and the sample D.

When the dipping time in HF is 420 seconds, a thickness of an oxide layer at the top corner is 310 Å for the sample C, and a thickness of an oxide layer is 360 Å for the sample D, when the oxide layer in the STI region is formed. Therefore, a thickness of an oxide layer at a top corner is relatively thick when the radius of the circle at the top corner of the STI region is relatively large (sample C), as compared to sample D, where a radius of the circle at the top corner of the STI region is relatively small.

Also, in the case where a radius R of an inscribed circle at a top corner of the STI region is 200 Å as in the samples A and C, a thickness of an oxide layer at the top corner formed during an oxide layer process after cleaning increases when a dipping time in HF is relatively long. That is, the sample C has an oxide layer having a thickness greater than that of an oxide layer of the sample A.

Also, in the case where a radius R of an inscribed circle at a top corner of the STI trench region where a slope is gentle (e.g., 400 Å as in the cases of samples B and D), a thickness of an oxide layer at the top corner formed during an oxide layer process after cleaning the STI region increases when a dipping time in HF during the cleaning process of the STI region is long. That is, the sample D has an oxide layer having a thickness greater than that of an oxide layer of the sample B.

In the first and second experiments, a thickness of an oxide layer has been measured under conditions that the first pad insulating layer is 150 Å thick, a pullback of the second pad insulating layer is 250 Å, an oxide layer during the cleaning process is 270 Å thick, an HV oxide layer is 350 Å thick, and polysilicon is deposited after the cleaning process.

In the embodiment of the present invention, a slope of the STI region can be calculated using an upper width and a lower width of the STI region.

A method for forming a trench according to the present invention provides the following effects.

According to the present invention, a top corner can be rounded by increasing a radius of an inscribed circle at a top corner of an STI trench region and controlling a dipping time in an HF-containing medium without adding a separate mask or process. Therefore, a process can be simplified.

Also, when the top corner of the STI region is rounded, it is possible to prevent or reduce a problem caused by damage generated by forming a thick oxide layer at a top corner during a subsequent cleaning process.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for forming a trench, the method comprising:
sequentially stacking a first insulating layer and a second insulating layer on a substrate having an isolation region and an active region therein;
forming a photoresist pattern on the second pad insulating layer;
sequentially patterning the second pad insulating layer and the first pad insulating layer using the photoresist pattern as a mask to expose a portion of a substrate in the isolation region; and
etching the substrate using the first and second pad insulating layers as a mask to form a trench such that an upper width of the trench is greater than a lower width of the trench.

2. The method according to claim 1, wherein further comprising rounding a top corner of the trench.

3. The method according to claim 2, wherein rounding the top corner of the trench comprises increasing an inner angle θ and a radius of an inscribed circle at the top corner by controlling an upper diameter and a lower diameter of the trench.

4. The method according to claim 3, wherein rounding the top corner of the trench further comprises controlling a slope of the trench.

5. The method according to claim 1, further comprising increasing a pullback length of the first insulating layer.

6. The method according to claim 2, wherein rounding the top corner of the trench comprises controlling a time of dipping the top corner in an HF-containing medium during a cleaning process.

7. The method according to claim 3, wherein the radius of the top corner of the trench is calculated using R=tan{[(θ^{α}/2)][a^{β}+b]}, where θ=tan⁻¹[{(e−f)/2}/g]+π/2, a is a pullback length of the first pad insulating layer, b is a pullback length of the second insulating layer, a={(C1×T1)²−C²}^{0.5}, b=C2×T2, α and β are weight factors of an oxidation process on the trench, C1 is an etching rate (Å/sec) of the first insulating layer, C2 is an etching rate (Å/sec) of the second insulating layer, T1 is an etching time (sec) of the first insulating layer, and T2 is an etching time (sec) of the second insulating layer.

8. The method according to claim 1, further comprising depositing an oxide layer in the trench.

9. The method according to claim 8, further comprising growing a liner oxide along sidewalls of the trench before depositing the oxide layer in the trench.

10. The method according to claim 8, further comprising polishing the oxide layer to remove the oxide layer from areas other than the trench.

11. The method according to claim 10, further comprising removing the second insulating layer.

12. The method according to claim 1, wherein the second insulating layer comprises a nitride layer.

13. The method according to claim 1, wherein the first insulating layer comprises a pad oxide layer.
